(19) United States
(12) Patent Application Publication
(10) Pub. No.: US 2017/0295660 A1
(43) Pub. Date: Oct. 12, 2017

(54) Actuating mechanism and waterproof case comprising the same

(71) Applicant: ASIA OPTICAL INDUSTRIES (HK) LIMITED, NT (CN)

(72) Inventors: WAI MAN VICTOR TSUI, NT (CN); ZHONG SHUANG ZHANG, NT (CN)

(21) Appl. No.: 15/416,503

(22) Filed: Jan. 26, 2017

(30) Foreign Application Priority Data
Apr. 12, 2016 (CN) 201620301288.0

(51) Int. Cl. H05K 5/06; G06F 3/02; G06F 3/044

(52) U.S. Cl. CPC H05K 5/065; G06F 3/044; G06F 3/0202

(57) ABSTRACT

The actuating mechanism provided by the present invention is used for actuating a capacitive touch screen of the digital products installed in a waterproof case, comprising an actuating assembly provided on the waterproof case; a probe connected to one end of the actuating assembly; a conductive connecting device provided on the waterproof case, and the probe is brought into contact with the conductive connecting device by the actuating assembly; and a trigger assembly provided on the capacitive touch screen and brought into contact with the touch screen, wherein the trigger assembly is connected with the conductive connecting device and is moved up and down by the actuating assembly, so that the probe and the conductive connecting device are brought into contact to complete the charge conduction. The actuating mechanism of the present invention can improve the drawbacks of the prior art, operating on any area of the touch screen at any position of the waterproof case, thereby operating the digital products. At the same time, it is possible to prevent the actuating mechanism on the waterproof case from blocking the graphic characters displayed on the touch screen. In addition, the trigger assembly is in continuous contact with the capacitive touch screen, with constant pressure, good conduction and stable work. The present invention also discloses a waterproof case based on the actuating mechanism.

### TECHNICAL FIELD

The present invention relates to an actuating assembly, more particularly to an actuating assembly of a waterproof case of a digital product which can be used to flexibly operate a digital product underwater. The invention also discloses a waterproof case using the actuating assembly digital product.

### BACKGROUND ART

In order to facilitate the operation of digital devices underwater by human body, at present, the digital products are equipped with waterproof cases cooperated with a variety of digital products to be able to operate the digital devices underwater, such as digital cameras, smart phones, IPAD, etc., but the existing waterproof cases are irrationally arranged on the whole, with inconvenient operation and poor actuating effect.

Based on this, the Chinese patent CN103034382B disclosed an actuating mechanism for actuating a capacitive touch screen of a digital device in a waterproof case. The actuating mechanism comprises an actuating shaft extending through an opening formed in the case, a button connected to the outer end of the shaft, a probe connected to the inner end of the shaft, and a biasing component adapted to drive the probe away from the touch screen; as such, the biasing force produced by pressing the button to resist the biasing component will move the probe toward the touch screen and contact the touch screen. The present invention also discloses a waterproof case having an actuating mechanism. The primary device and operating principle of the actuating structure of this patent is as follows: a waterproof case body, an actuating shaft extending through an opening formed on the case body, a button connected to the outer end of the shaft, a probe connected to an inner end of the shaft and a biasing component adapted to drive the probe away from the touch screen; the biasing force produced by pressing the button to resist the biasing component will move the probe toward the touch screen and contact the touch screen. The button, shaft and probe may be made from a material capable of conducting charge.

In this actuating structure, the actuating shaft playing a role of connection can only move up and down in an opening formed in the body case, and a button connected to the upper end of the actuating shaft and a probe connected to the inner end of the shaft also move in the same direction. Therefore, this actuating structure can only operate the vertical portion area on the touch screen corresponding to the actuating shaft during work. The point on the waterproof case which is perpendicular to the touch screen is not suitable for installing the actuating structure, or the installation of the actuating structure will interfere with other parts and exert great restrictions.

For this reason, there is an urgent need for a novel actuating mechanism of a waterproof case of a digital device in order to improve the above-mentioned drawbacks and problems in the prior art, and can operate any area of the touch screen at any position on the waterproof case, thereby operating the digital products, and will not interfere with other parts.

### SUMMARY OF THE INVENTION

It is an object of the present invention to solve the above-mentioned problems in the prior art and provide an actuating mechanism capable of operating a touch screen at any position on a waterproof case without interfering with other parts; and provide a waterproof case using the actuating mechanism.

In order to reach the above object, according to one aspect of the present invention, the following technical solution is adopted for the actuating mechanism of the present invention:

an actuating mechanism for actuating a capacitive touch screen of a digital product installed in the waterproof case, comprising:

an actuating assembly provided on the waterproof case for being convenient for manual operation;

a probe connected to one end of the actuating assembly and moved up and down by the actuating assembly;

a conductive connecting device provided on the waterproof case, and the probe is brought into contact with the conductive connecting device by the actuating assembly; and

a trigger assembly provided on the capacitive touch screen and brought into contact with the touch screen, wherein the trigger assembly is connected with the conductive connecting device and is moved up and down by the actuating assembly, so that the probe and the conductive connecting device are brought into contact to complete the charge conduction.

More preferably, the conductive connecting device is provided with a conductive contact piece, one end of which is located below the probe of the actuating assembly to be ready for triggering, and the other end is in connecting conduction with the trigger assembly.

Further, according to the actuating mechanism of the present invention, the actuating assembly comprises:

an actuating shaft extending past and through an opening provided in the waterproof case;

a button connected to one end of the actuating assembly; and

a first resilient member provided on the actuating shaft, such that the actuating shaft is moved up and down by the resilient member.

According to one embodiment of the actuating mechanism of the present invention, the probe is provided on the other end of the actuating shaft. A first fixing member is provided at an inner end of the actuating shaft so that the probe is held in a position in close proximity to an inner surface of the waterproof case.

According to one embodiment of the actuating mechanism of the present invention, the trigger assembly comprises:

a contact shaft perpendicular to an application point on the touch screen; and

a trigger plate connected to the contact shaft and held in contact with the touch screen.

According to one embodiment of the actuating mechanism of the present invention, the trigger assembly comprises a second resilient member for leveling the trigger plate against the touch screen. More preferably, the first and second resilient members are all springs.

In the actuating mechanism of the present invention, the trigger assembly comprises a second fixing member for fixing the contact shaft to one end of the conductive connecting device.

In the actuating mechanism of the present invention, the actuating mechanism comprises a sealing member for sealing a gap between the actuating shaft and the opening of the waterproof case.

According to another aspect of the present invention, the present invention also provides a waterproof case which is suitable for digital products such as digital cameras, PDAs, smart phones, IPADs, etc., and the waterproof case comprises:

a waterproof case body; and

an actuating mechanism, comprising:

an actuating assembly provided on the waterproof case for being convenient for manual operation;

a probe connected to one end of the actuating assembly and moved up and down by the actuating assembly;

a conductive connecting device provided on the waterproof case, and the probe is brought into contact with the conductive connecting device by the actuating assembly; and

a trigger assembly provided on the capacitive touch screen and brought into contact with the touch screen, wherein the trigger assembly is connected with the conductive connecting device and is moved up and down by the actuating assembly, so that the probe and the conductive connecting device are brought into contact to complete the charge conduction.

More preferably, the conductive connecting device is provided with a conductive contact piece, one end of which is located below the probe of the actuating assembly to be ready for triggering, and the other end is in connecting conduction with the trigger assembly.

According to the waterproof case of the present invention, the actuating assembly comprises:

an actuating shaft extending past and through an opening provided in the waterproof case;

a button connected to one end of the actuating assembly; and

a first resilient member provided on the actuating shaft, such that the actuating shaft is moved up and down by the resilient member.

According to the waterproof case of the present invention, the probe is provided on the other end of the actuating shaft.

According to the waterproof case of the present invention, a first fixing member is provided at an inner end of the actuating shaft so that the probe is held in a position in close proximity to an inner surface of the waterproof case.

According to the waterproof case of the present invention, the trigger assembly comprises:

a contact shaft perpendicular to an application point on the touch screen; and

a trigger plate connected to the contact shaft and held in contact with the touch screen.

According to the waterproof case of the present invention, the trigger assembly comprises a second resilient member for leveling the trigger plate against the touch screen.

According to the waterproof case of the present invention, the resilient members are all springs.

According to the waterproof case of the present invention, the trigger assembly comprises a second fixing member for fixing the contact shaft to one end of the conductive connecting device.

According to the waterproof case of the present invention, the actuating mechanism comprises a sealing member for sealing a gap between the actuating shaft and the opening of the waterproof case.

Further, the first and second fixing members are both fixing snap rings.

The actuating mechanism of the present invention can improve the drawbacks of the prior art, operating on any area of the touch screen at any position of the waterproof case, thereby operating the digital products, and will not interfere with other parts, and it is easy to use and convenient to operate. The structure can effectively avoid the restrictions on the actuating structure in terms of operation and vision in the prior art, the user can reasonably select where to install the actuating mechanism of the present invention according to their operating habits or the structure of the waterproof case, and the trigger assembly is in continuous contact with the capacitive touch screen, with constant pressure, good conduction and stable work. In addition, the waterproof case of the present invention is installed based on the actuating mechanism of the present invention, and has the advantages of excellent sealing effect and easy to use in large scale excluding the advantages mentioned above.

### BRIEF DESCRIPTION OF THE DRAWINGS

The invention will now be described in details with reference to the accompanying drawings, in which:

FIG. 1 is a schematic view of an overall structure of an actuating mechanism according to one embodiment of the present invention;

FIG. 2 is a schematic view of an overall structure of the actuating mechanism of FIG. 1;

FIG. 3 is a schematic structural view of a waterproof case according to an embodiment of the present invention, in which an actuating mechanism is not shown; and

FIG. 4 is a schematic structural view of a waterproof case according to an embodiment of the present invention, in which an actuating mechanism is shown.

### DETAILED DESCRIPTION OF THE INVENTION

The specific structure of the actuating mechanism and the waterproof case of the present invention will be described in detailed illustration and description below with reference to the accompanying drawings and the embodiments.

In this text, the term “connected” refers to a state of one element with another element, and does not necessarily indicate the case that one element is fixed to, fastened to, or otherwise attached to another element. In addition, the term “connected” means that one element is directly or indirectly connected to another element, or is in mechanical or electrical communication with another element.

The digital products of the present invention comprise electronic devices having capacitive screens such as digital cameras, PDAs, smart phones, IPADs and the like, and for the convenience of explanation, the technical solution of the present invention will be described below using a digital camera as an example.

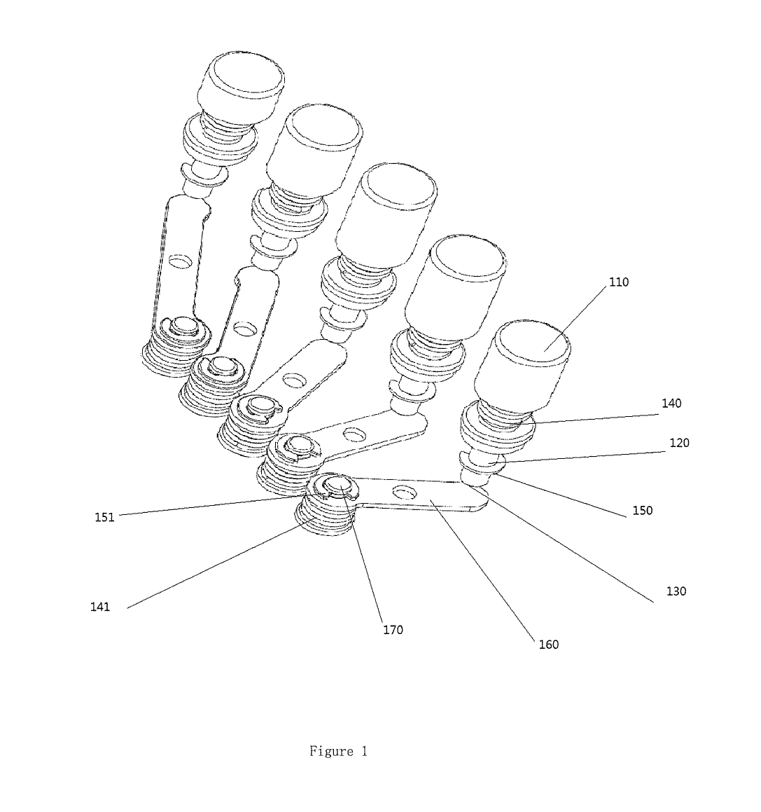

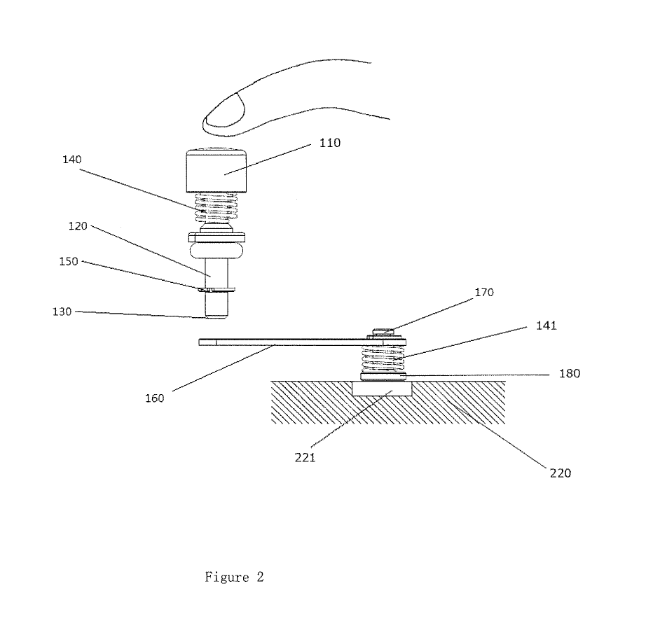

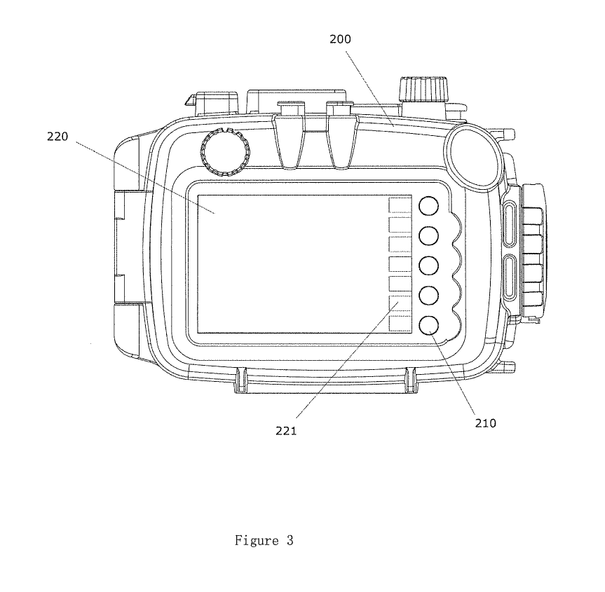

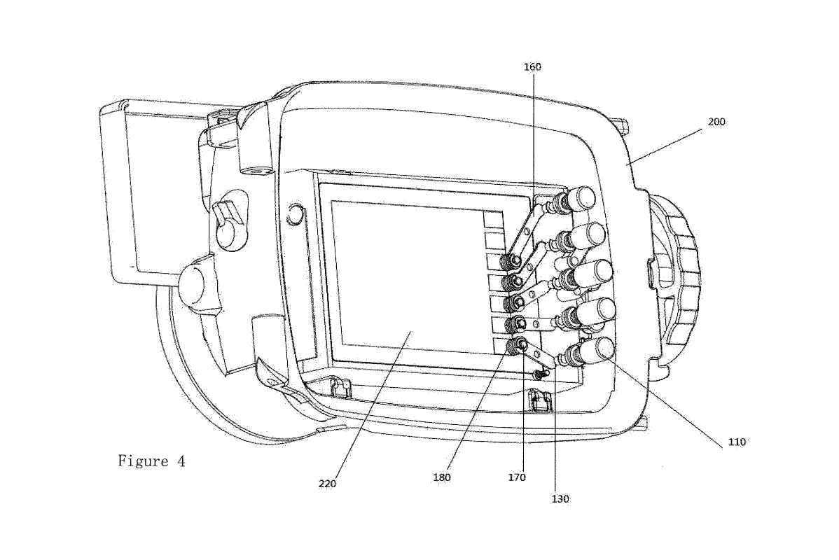

As shown in FIGS. 1 to 4, the actuating mechanism of the present invention is used for actuating a capacitive touch screen 220 of the digital products installed in a waterproof case 200, comprising an actuating assembly provided on the waterproof case 200 for being convenient for manual operation. The actuating assembly comprises an actuating shaft 120 extending past and through an opening 210 provided in the waterproof case 200; a button 110 connected to one end of the actuating shaft 120; and a first resilient member 140 provided on the actuating shaft 120, the actuating shaft 120 is moved up and down in a direction by the resilient member 140, wherein the other end of the actuating shaft 120 is provided with a probe 130. A plurality of actuating mechanisms are shown in FIG. 1, all of which are mounted on the waterproof case 200 of the present invention, and only one of the structures of the present invention is described in detail herein, as shown in FIG. 2.

The actuating mechanism further comprises a conductive connecting device 160, the probe 130 is brought into contact with the conductive connecting device 160 by the actuating assembly. More preferably, in one embodiment, the conductive connecting device 160 is provided with a conductive contact piece, one end of which is located below the probe of the actuating assembly to be ready for triggering, and the other end is in connecting conduction with the trigger assembly.

Further, the actuating mechanism also comprises a trigger assembly, wherein the trigger assembly is connected with the conductive connecting device 160, and is moved up and down by the actuating assembly, so that the probe 130 and the conductive connecting device 160 are brought into contact to complete the charge conduction. Further, the trigger assembly comprises a contact shaft 170 which is perpendicular to an application point 221 on the touch screen 220; and a trigger plate 180 connected to the contact shaft 170 and held in continuous contact with the touch screen 220.

According to one embodiment of the actuating mechanism of the present invention, the trigger assembly comprises a second resilient member 141 for leveling the trigger plate 180 against the touch screen 220. More preferably, the first and second resilient members are all springs.

More preferably, according to one embodiment of the actuating mechanism of the present invention, a first fixing member 150 is provided at an inner end of the actuating shaft 120 so that the probe 130 is held in a position in close proximity to an inner surface of the waterproof case 200. Furthermore, according to another embodiment of the present invention, in the actuating mechanism, the trigger assembly comprises a second fixing member 151 for fixing the contact shaft 170 to one end of the conductive connecting device 160. Preferably, the first and second fixing members are both fixing snap rings, so as to play a fixing role.

According to the actuating mechanism of the present invention, the actuating mechanism comprises a sealing member for sealing a gap between the actuating shaft and the opening of the waterproof case.

The present invention also provides a waterproof case which is suitable for digital products such as digital cameras, PDAs, smart phones, IPADs, etc., and the waterproof case comprises: the actuating assembly including an actuating shaft 120 extending past and through an opening 210 provided in the waterproof case 200; a button 110 connected to one end of the actuating shaft 120; and a first resilient member 140 provided on the actuating shaft 120, the actuating shaft 120 is moved up and down in a direction by the resilient member 140, wherein the other end of the actuating shaft 120 is provided with a probe 130.

The actuating mechanism further comprises a conductive connecting device 160, the probe 130 is brought into contact with the conductive connecting device 160 by the actuating assembly.

Further, the actuating mechanism also comprises a trigger assembly, wherein the trigger assembly is connected with the conductive connecting device 160, and is moved up and down by the actuating assembly, so that the probe 130 and the conductive connecting device 160 are brought into contact to complete the charge conduction. Further, the trigger assembly comprises a contact shaft 170 which is perpendicular to an application point 221 on the touch screen 220; and a trigger plate 180 connected to the contact shaft 170 and held in continuous contact with the touch screen 220 for the purpose of controlling the application.

According to one embodiment of the actuating mechanism of the present invention, the trigger assembly comprises a second resilient member 141 for leveling the trigger plate 180 against the touch screen 220. More preferably, the first and second resilient members are all springs.

More preferably, according to one embodiment of the actuating mechanism of the present invention, a first fixing member 150 is provided at an inner end of the actuating shaft 120 so that the probe 130 is held in a position in close proximity to an inner surface of the waterproof case 200. Furthermore, according to another embodiment of the present invention, in the actuating mechanism, the trigger assembly comprises a second fixing member 151 for fixing the contact shaft 170 to one end of the conductive connecting device 160. Preferably, the first and second fixing members are both fixing snap rings, so as to play a fixing role.

According to the waterproof case 200 of the present invention, the actuating mechanism is provided with a sealing member (not shown) for sealing a gap (not shown) between the actuating shaft 120 and the opening 210 of the waterproof case 200. More preferably, the resilient member is an 0-ring made from rubber or plastics to well play the sealing role.

The actuating mechanism of the present invention can improve the drawbacks of the prior art, operating on any area of the touch screen at any position of the waterproof case, thereby operating the digital products, and will not interfere with other parts, and it is easy to use and convenient to operate. The structure can effectively avoid the restrictions on the actuating structure in terms of operation and vision in the prior art, the user can reasonably select where to install the actuating mechanism of the present invention according to their operating habits or the structure of the waterproof case. In addition, the waterproof case of the present invention is installed based on the actuating mechanism of the present invention, and has the advantages of excellent sealing effect and easy to use in large scale excluding the advantages mentioned above.

The above disclosure is only a preferred embodiment of the present invention, which of course is not intended to limit the scope of the present invention. It is therefore intended that equivalents, modifications, and variations in accordance with the following claims are embraced by the present invention.

1. An actuating mechanism for actuating a capacitive touch screen of a digital product installed in the waterproof case, wherein the actuating mechanism comprises:
an actuating assembly provided on the waterproof case for being convenient for manual operation;
a probe connected to one end of the actuating assembly and moved up and down by the actuating assembly;
a conductive connecting device provided on the waterproof case, and the probe is brought into contact with the conductive connecting device by the actuating assembly; and
a trigger assembly provided on the capacitive touch screen and brought into contact with the touch screen, wherein the trigger assembly is connected with the conductive connecting device and is moved up and down by the actuating assembly, so that the probe and the conductive connecting device are brought into contact to complete the charge conduction.

2. The actuating mechanism according to claim 1, wherein the actuating assembly comprises:
an actuating shaft extending past and through an opening provided in the waterproof case;
a probe connected to one end of the actuating assembly; and
a first resilient member provided on the actuating shaft, such that the actuating shaft is moved up and down by the resilient member.

3. The actuating mechanism according to claim 1, wherein the probe is provided on the other end of the actuating shaft.

4. The actuating mechanism according to claim 1, wherein a first fixing member is provided at an inner end of the actuating shaft so that the probe is held in a position in close proximity to an inner surface of the waterproof case.

5. The actuating mechanism according to claim 1, wherein the trigger assembly comprises:
a contact shaft perpendicular to an application point on the touch screen; and
a trigger plate connected to the contact shaft and held in contact with the touch screen.

6. The actuating mechanism according to claim 5, wherein the trigger assembly comprises a second resilient member for leveling the trigger plate against the touch screen.

7. The actuating mechanism according to claim 6, wherein the resilient members are all springs.

8. The actuating mechanism according to claim 5, wherein the trigger assembly comprises a second fixing member for fixing the contact shaft to one end of the conductive connecting device.

9. The actuating mechanism according to claim 1, wherein the conductive connecting device is provided with a conductive contact piece, one end of which is located below the probe of the actuating assembly to be ready for triggering, and the other end is in connecting conduction with the trigger assembly.

10. The actuating mechanism according to claim 2, wherein the actuating mechanism comprises a sealing member for sealing a gap between the actuating shaft and the opening of the waterproof case.

11. A water-proof case, comprising:
a waterproof case body; and
an actuating mechanism, comprising:
an actuating assembly provided on the waterproof case for being convenient for manual operation;
a probe connected to one end of the actuating assembly and moved up and down by the actuating assembly;
a conductive connecting device provided on the waterproof case, and the probe is brought into contact with the conductive connecting device by the actuating assembly; and
a trigger assembly provided on the capacitive touch screen and brought into contact with the touch screen, wherein the trigger assembly is connected with the conductive connecting device and is moved up and down by the actuating assembly, so that the probe and the conductive connecting device are brought into contact to complete the charge conduction.

12. The waterproof case according to claim 11, wherein the actuating assembly comprises:
an actuating shaft extending past and through an opening provided in the waterproof case;
a button connected to one end of the actuating assembly; and
a first resilient member provided on the actuating shaft, such that the actuating shaft is moved up and down by the resilient member.

13. The waterproof case according to claim 12, wherein the probe is provided on the other end of the actuating shaft.

14. The waterproof case according to claim 12, wherein a first fixing member is provided at an inner end of the actuating shaft so that the probe is held in a position in close proximity to an inner surface of the waterproof case.

15. The waterproof case according to claim 11, wherein the trigger assembly comprises:
a contact shaft perpendicular to an application point on the touch screen; and
a trigger plate connected to the contact shaft and held in contact with the touch screen.

16. The waterproof case according to claim 15, wherein the trigger assembly comprises a second resilient member for leveling the trigger plate against the touch screen.

17. The waterproof case according to claim 16, wherein the resilient members are all springs.

18. The waterproof case according to claim 12, wherein the trigger assembly comprises a second fixing member for fixing the contact shaft to one end of the conductive connecting device.

19. The waterproof case according to claim 11, wherein the conductive connecting device is provided with a conductive contact piece, one end of which is located below the probe of the actuating assembly to be ready for triggering, and the other end is in connecting conduction with the trigger assembly.

20. The waterproof case according to claim 12, wherein the actuating mechanism comprises a sealing member for sealing a gap between the actuating shaft and the opening of the waterproof case.
